(19) United States
(12) Patent Application Publication
(10) Pub. No.: US 2010/0231812 A1
(43) Pub. Date: Sep. 16, 2010

(54) MICRODISPLAY IMAGER SYSTEM AND METHOD

(75) Inventor: Estill Thone Hall, JR., Fishers, IN (US)

Correspondence Address: FLETCHER YODER P.C., 7915 FM 1960 RD. WEST, SUITE 330, HOUSTON, TX, 77070, US

(73) Assignee: SHENZHEN TCL NEW TECHNOLOGY LTD., Shekou, Shenzhen, Guangdong (CN)

(21) Appl. No.: 12/740,983

(22) PCT Filed: Feb. 22, 2008
(86) PCT No.: PCT/US2008/054700

§ 371 Date: Apr. 30, 2010

(30) Foreign Application Priority Data
Dec. 25, 2007 (CN) 200710125503.1

(51) Int. Cl. H04N 3/26; H01L 33/58; F21V 1/00; F21V 9/00

(52) U.S. Cl. 348/745; 257/91; 362/235; 362/231; 257/E33.067; 348/E03.048

(57) ABSTRACT

The present invention is directed to an illumination system. The illumination system comprises a plurality of light emitting diodes (LEDs) adapted to emit light. The illumination system further comprises a plurality of lens elements disposed subsequent to the LEDs, such that a number of lens elements corresponds to a number of LEDs. Further the plurality of lens elements are adapted to redirect the light emitted by the LEDs on a lens.

### FIELD OF THE INVENTION

The present invention relates generally to video display and projection systems. More specifically, the present invention relates to illumination systems of video display and projection systems.

### BACKGROUND OF THE INVENTION

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

Typically, video display and projection systems employ an illumination system (for example, a light engine) for generating light ultimately used to form an image. Microdisplay systems such as digital light processor (DLP) systems typically include an illumination system that utilizes a specialized high pressure mercury arc lamp as an illumination source. Such a lamp initially provides the illumination system with white light, which is subsequently split or dispersed using optical devices (e.g., color wheel, filters, etc.) into three primary colors, namely, red green and blue (RGB). Thereafter, the RGB light is combined using yet additional optical devices for generating a colored image. The optical and other devices typically used to disperse and, thereafter, recombine the light may occupy a substantial amount of space within the illumination and projection systems in which they are employed. Accordingly, these optical devices may dictate that the video display unit in which they are disposed is undesirably large.

Further, the arc lamps used in such systems may have a relatively short lifetime and may require frequent replacement. Moreover, replacing the lamp may be cumbersome, requiring major disassembly of the entire display system and/or some of its elements. In addition, mercury contained within some of the arc lamps render those lamps environmentally unfriendly.

### BRIEF DESCRIPTION OF THE DRAWINGS

Advantages of the invention may become apparent upon reading the following detailed description and upon reference to the drawings in which:

FIG. 1 is a block diagram of a video unit in accordance with an exemplary embodiment of the present invention;

FIG. 2 is a block diagram of an illumination system in accordance with an embodiment of the present invention;

FIG. 3 is perspective view of an illumination system having a lenslet assembly, in accordance with an exemplary embodiment of the present invention; and

FIG. 4 is a process flow diagram showing a method for illuminating a projection system in accordance with an exemplary embodiment of the present invention.

### DETAILED DESCRIPTION

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

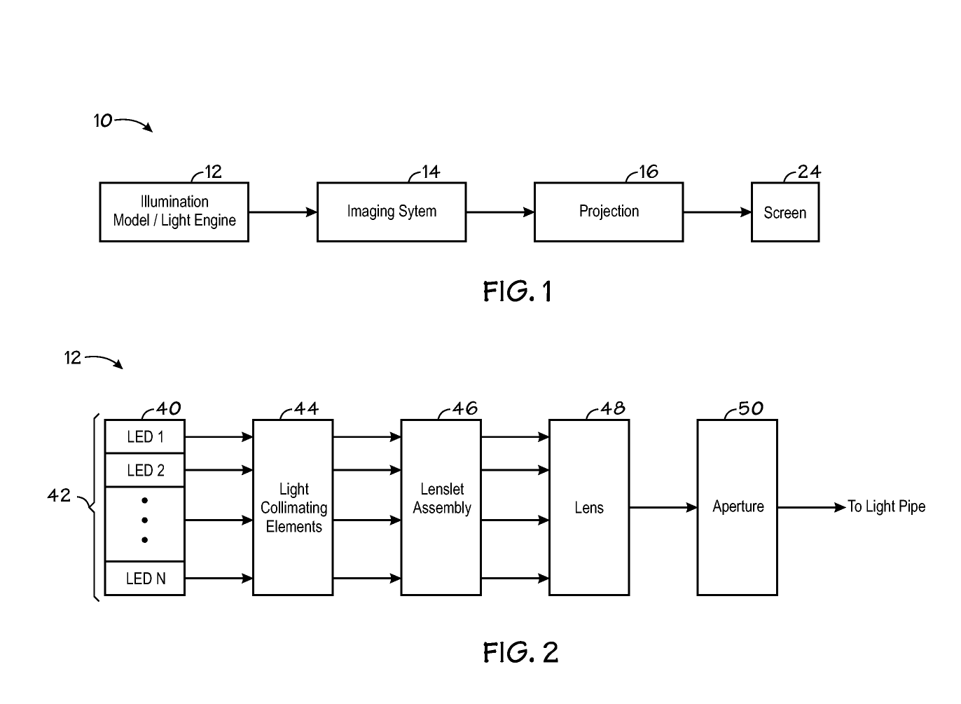

Turning initially to FIG. 1, a block diagram of a video unit in accordance with one exemplary embodiment of the present invention is illustrated and generally designated by a reference numeral 10. In the illustrated embodiment, the video unit 10 may comprise a Digital Light Processing (“DLP”) projection television or projector or the like. In another embodiment, the video unit 10 may comprise a liquid crystal display (“LCD”) projection television or projector or the like. In still other embodiments, the video unit 10 may comprise a liquid crystal on silicon (LCOS) projector, a high temperature poly-silicon (HTPS) or another suitable form of projection television or display.

The video unit 10 includes a light engine/illumination system 12. The illumination system 12 is configured to generate white or colored light that can be employed by an imaging system 14 to create a video image. As will be discussed in further detail below, the illumination system 12 includes optical and electro-optical components adapted to replace arc lamps otherwise used in conventional systems. The illumination system 12 includes a collection of pulsed light emitting diodes (LEDs) adapted to emit, for example, RGB light at various intensities. As will be further shown below, the illuminations system 12 further includes an optical device, referred to herein as a lenslet assembly. The lenslet assembly is a collection of lens elements whose number is equal to the number of the above-mentioned LEDs. The lenslet assembly is adapted to collect and further transmit the RGB light emanating from the LEDs onto an aperture. In this manner, the illumination system 12 is configured to efficiently convey the light provided by the illumination system 12 onward to a light pipe of the video unit 10. As those skilled in the art will appreciate, the term light pipe used herein refers to components and optical connections/coupling of the video unit 10 disposed subsequent to the illumination system 12. As will be described further below, such components of the video unit 10 may include an imaging system, a projection system, a screen, optical devices couplings and so forth.

Hence, the illumination system 12 utilizes a plurality of LEDs instead of an arc lamp as an illumination source. In other words, rather than employing a lamp for generating white light and components (e.g., color wheels, dichroic mirrors, polarizes, filters, etc.) for dispersing and separating the white light, the illumination system 12 efficiently combines the light produced by the LEDs at the outset to form colored and white light at various intensities. The video unit 10, therefore, may be made to be smaller in size as compared to those systems employing arc lamps and/or similar devices used for generating white light as an illumination source.

As described above, the illumination system 12 may be configured to project, shine, or focus colored light at the imaging system 14. The imaging system 14 may be configured to employ the colored light to create images suitable for display on a screen 24. The imaging system 14 may be configured to generate one or more pixel patterns that can be used to calibrate pixel shifting in the video unit 10. In one embodiment, the imaging system 14 comprises a DLP imaging system that employs one or more DMDs to generate a video image using the colored light. In another embodiment, the imaging system 14 may employ an LCD projection system. It will be appreciated, however, that the above-described exemplary embodiments are not intended to be exclusive, and that alternate embodiments, any suitable form of imaging system 14 may be employed in the video unit 10.

The imaging system 14 illustrated in FIG. 1 may be configured to project images into a projection lens assembly 16. The projection lens assembly 16 may include one or more lenses and/or mirrors that project the image created by the imaging system 14 onto the screen 24.

FIG. 2 is a block diagram of the illumination system 12 in accordance with an exemplary embodiment of the present invention. As mentioned above, the illumination system 12 includes light generating and collecting components adapted to convey the colored light to imaging and projection devices of the video unit 10 (FIG. 1). The illumination system 12 includes an LED module 40 adapted to house a plurality of LEDs 42. Each of the LEDs 42 may be pulsed at a certain fast rate. Further, each of the LEDs 42 contained within the module 40 may be adapted to emit red, green or blue light. Other embodiments may incorporate LEDs, i.e., LEDs 42, adapted to emit light of various colors, some of which may be different from red, green or blue. In addition, the module 40 may be adapted to house N LEDs. In an exemplary embodiment, the module 40 may be adapted to house up to eleven LEDs. In other exemplary embodiments, the module 40 may include up to five or seven LEDs. In still other exemplary embodiments, the illumination system 12 may be adapted to include multiple LED modules, such as the modules 40. In such embodiments, each of the modules 40 may be adapted to house a different number of LEDs. It should be noted that the number of LEDs included within each of the modules 40 may be determined by system design and/or operation criteria and/or by cost effective goals.

Hence, the module 40 is adapted to house combinations of RGB LEDs. Such combinations can be used, for example, to accentuate and/or suppress light of a specific color. For instance, a suitable combination of LEDs can configure the video unit 10 to produce images having hues that are relatively greater in red than blue. This may be achieved by including within the module 40 a greater number LEDs producing red light than those LEDs producing blue light. Similarly, the module 40 may be adapted to house other combinations of LEDs, such as those envisioned to output light with enhanced and/or suppressed color(s) of different kinds.

The ability to incorporate and/or change the amount of LEDs within the illumination system 12 is facilitated by a modular design of the module 40. That is, each of the LEDs 42 may be independently coupled to the module 40 such that one or more of the LEDs 42 can be replaced and/or removed form the module 40 with minimal effort. Further, should one or more of the LEDs 42 malfunction or otherwise become idle, the video unit 10 may continue to project images despite some loss in color and/or brightness. Hence, unlike systems employing arc lamps whose malfunction renders the entire video unit nonfunctional, the present technique enables the video unit to continue operating even though one or more of he LEDs is non operational. Further, those skilled in the art will appreciate that the average lifetime of an LED is far greater than the average lifetime of an arc lamp. This yet provides another advantage of using the LEDs 42 as an illumination source rather the mercury lamp used in conventional systems.

The illumination system 12 further includes a plurality light collimating elements or collimators 44 adapted to efficiently collect the light produced by the LEDs 42. In an exemplary embodiment, each of collimators 44 may be disposed near or directly adjacent to each of the LEDs 42. In other exemplary embodiments, each of the collimators 44 may surround each of the LEDs 42 such that the LEDs 42 may be partially embedded within the collimators 44. Each of the collimators 44 is adapted to intake a maximal amount of light emanating from the LED to which the collimator is coupled. In so doing, the collimators 44 increase the light gathering ability of the illumination system 12. This ensures that the majority of the light produced by the LEDs 42 can be efficiently provided to and utilized by subsequent optical components of the video unit 10 for generating an image.

The illumination system 12 further includes a lenslet assembly 46. The lenslet assembly 46 includes a plurality of optical components, referred to herein as lenslets or lens elements. Hence, the lenslet assembly 46 is a collection of individual lenslets or lens elements. The number of lenslets included in the lenslet assembly 46 corresponds to the number of LEDs 42 included in the module 40. Each of the lenslets is adapted to receive light emitted by a respective LED 42 and collimator 44. Further, after receiving the light for the respective LED, each of the lenslets of the assembly 46 is adapted to redirect the light onto a lens 48 disposed subsequent to the lenslet assembly 46. As will be further shown below, each of the lenslets 46 is geometrically oriented relative to an axis for optimally receiving and redirecting the light emanating from each of the respective LEDs 42 onto the lens 48. In so doing, the lenslets 46 ensures that the lens 48 receives and collects a maximal amount of light emitted by the LEDs 42. Further, once the lens 48 receives the redirected light, the lens 48 focuses the light onto an aperture 50. The aperture 50 is adapted to transmit the light into a light pipe comprising additional imaging and projection components, as discussed hereinabove in relation to FIG. 1.

The lenslet assembly 46 is adapted to provide a unique intensity distribution at the aperture 50 for each of the LEDs 42. The intensity distribution for each of the LEDs 42 at the aperture 50 depends on the location of each of the LEDs 42 in module 40 and on the orientation of the respective lenslets 46 relative to lens 48. By virtue of including the lenslet assembly 46 within the illumination system 12, proper intensity levels of the LEDs 42 are obtained at the aperture 50 for projecting an image. In other words, absent the lenslet assembly 46, the light emerging from the LEDs 42 cannot be collected efficiently at aperture 50 for projecting a viewable image.

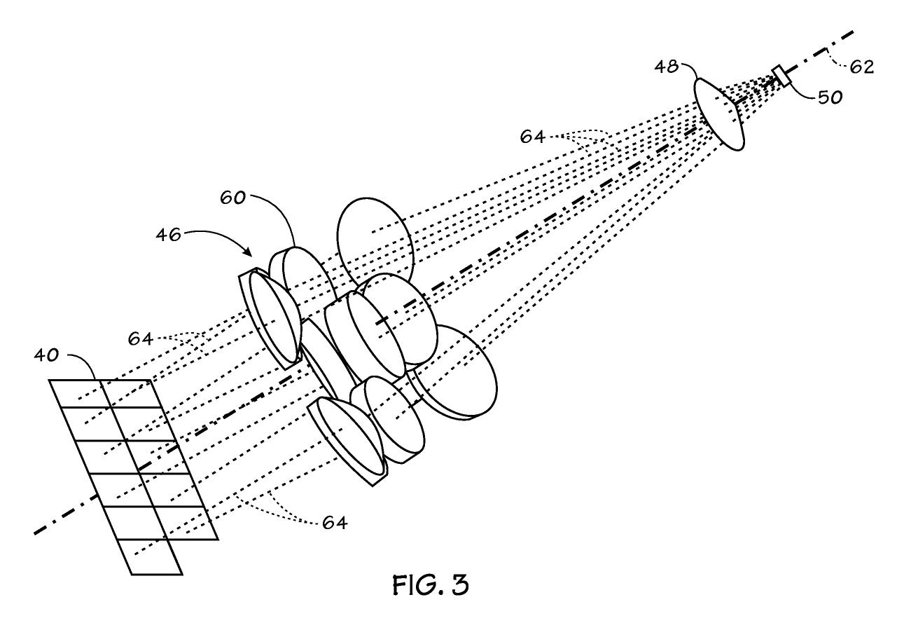

FIG. 3 is perspective view of an illumination system including a lenslet assembly, in accordance with an embodiment of the present technique. The illumination system and the lenslet assembly depicted in FIG. 3 are similar to those discussed herein in relation to FIG. 2. As illustrated, the lenslet assembly 46 is disposed between the module 44 and the lens 48. In the illustrated embodiment, the lenslet assembly 46 forms a structure that includes eleven lenslets 60, corresponding to eleven LEDs included within the module 40. Each of the lenslets 60 may be made up from an optical plastic, such as an acrylic complex or a similar material. Each of the lenslets 60 may be molded into a semi-convex structure having a lens-like structure. In the illustrated embodiment, each of the lenslets 60 may have one flat-shaped side facing the module 40, and one relatively curved/convex shaped-side facing the lens 48.

As illustrated by FIG. 3, each of the lenslets 60 is disposed about an axis 62. While in the illustrated embodiment, the lenslet assembly 46 may be disposed symmetrically transverse relative to the axis 62, other embodiments may include disposing the lenslet assembly 46 asymmetrically transverse relative to the axis 62.

Further, each of the lenslets 60 may generally have a unique orientation relative to the axis 62, the module 40 (LEDs 42) and the lens 48. The unique orientation of each of the lenslets 60 relative to the aforementioned components ensures that each of the lenslets 60 optimally captures the light emitted by the respective LEDs disposed within the module 40. In other words, each of the lenslets 60 is adapted to optically couple its respective LED 42 to the lens 48 and aperture 50.

Hence, the lenslet assembly 46 overall forms a concave/convex structure adapted to intercept and redirect light rays 64 emerging onto the lens 48. As illustrated, the light rays 64 initially emerge from the module 40 in a somewhat divergent manner before they impinge the lenslet assembly 46. That is, between the module 40 and the lenslet assembly 46, the light rays 64 veer away from the axis 62. After propagating through the lenslet assembly 46, the light rays 64 veer towards the axis 62, as they converge onto the lens 48. After impinging lens 48, the rays 64 further converge towards the axis 62 until the rays 64 to form uniform beam having a relatively small diameter. Hence, the lens 48 reshapes the rays 64 so that those can enter the aperture 50 and propagated into a light pipe of the video unit 10 (FIG. 1). The processing of the light rays 64 by the lenslets 60 and the lens 48 is adapted to optimize efficiencies of usable light for each of the LEDs 42 at aperture 50.

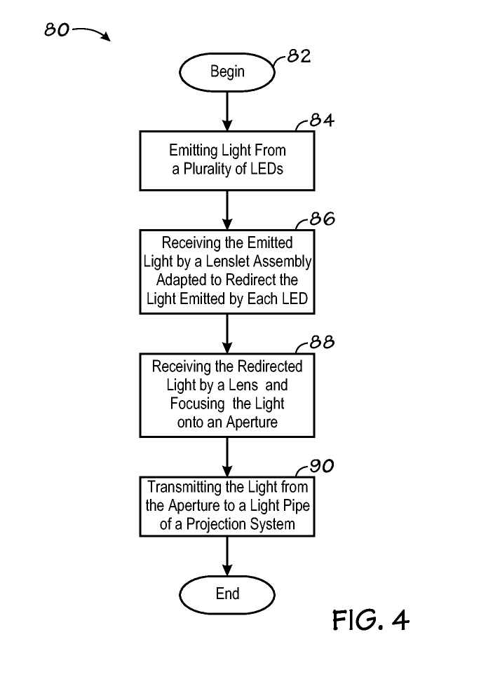

FIG. 4 is a process flow diagram showing a method for illuminating a projection system in accordance with an exemplary embodiment of the present invention. The method is generally referred to by the reference number 80. The method 80 can be applied to the illumination system 12 described above in relation to FIGS. 1-3. The method 80 begins at block 82. Process flow then proceeds to block 84, in which an illumination system of a video unit emits light by a plurality of LEDs, such as the LEDs 42 of the module 40. Block 84 may also include collimating the emitted light by collimators, such as the collimators 44. As mentioned above, the collimation increases the amount of light available for projecting an image onto a screen of the video unit. Thereafter, at block 86, the light emitted by the LEDs 42 is received by a lenslet assembly, such as the lenslet assembly 46, adapted to redirect the light emanating by the LEDs towards a lens, such as lens 48 (FIGS. 2 and 3). It should be appreciated that the act of receiving and redirecting the light, as performed at block 86, is applied by each lenslet to each light ray emanating from a respective LED contained within the module 40.

From block 86 the method 80 proceeds to block 88, where the light redirected by the lenslet assembly is received by the lens. At block 88, the lens focuses the light onto an aperture, such as aperture 50. Next, at block 90, the light gathered by the aperture is provided to a light pipe for projecting an image by the video unit.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. An illumination system, comprising:
a plurality of light emitting diodes (LEDs) adapted to emit light; and
a plurality of lens elements disposed subsequent to the LEDs, wherein a number of lens elements corresponds to a number of LEDs; and
wherein the plurality of lens elements is adapted to redirect the light emitted by the LEDs on a lens.

2. The illumination system of claim 1, comprising an aperture disposed subsequent to the lens.

3. The illumination system of claim 1, wherein each of the LEDs is adapted emit red, green or blue light.

4. The illumination system of claim 1, wherein the LEDs are disposed within a module that enables independent replacement of each of the LEDs within the illumination system.

5. The illumination system of claim 1, wherein each of the plurality of lens elements is disposed about a line joining the plurality of LEDs, the plurality of lens elements and the lens.

6. The illumination system of claim 5, wherein the plurality of lens elements is disposed symmetrically transverse relative to the line.

7. The illumination system of claim 5, wherein the plurality of lens elements is disposed asymmetrically transverse relative to the line.

8. The illumination system of claim 1, wherein each lens element is uniquely disposed relative to a respective LED of the plurality of LEDs.

9. The illumination system of claim 1, wherein the plurality of lens elements is adapted to increase the efficiency of light provided to a light pipe of the video unit.

10. A method of operating an illumination system of a video unit, comprising:
emitting light signals from a plurality of light emitting diodes (LEDs);
redirecting the emitted light by a plurality of lens elements whose number is equal to a number of the LEDs comprising the plurality of LEDs;
receiving the redirected light by a lensadapted to focus the light onto an aperture; and
retransmitting the light from the aperture to a light pipe of the video unit.

11. The method of claim 10, comprising redirecting the light about a line joining the plurality of LEDs, the plurality of lens elements and the lens.

12. The method of claim 10, comprising pulsing the light emitted by each of the plurality of LEDs.

13. The method claim 10, comprising emitting red, green and blue light by the plurality of LEDs.

14. The method of claim 10, comprising collimating the light emitted by the plurality of LEDs before receiving the light by the plurality of lens elements.

15. The method of claim 10, wherein redirecting comprises receiving light by one of the plurality of lens elements from a respective one of the plurality of LEDs, and transmitting the light onto the lens.

16. A video unit, comprising:
an illumination system, comprising:
a plurality of light emitting diodes (LEDs) adapted to emit light;
a plurality of lens elements disposed subsequent to the LEDs, wherein a number of lens elements corresponds to the number of LEDs, and wherein the plurality of lens elements is adapted to redirect the light emitted by the LEDs on a lens.
an imaging system adapted to form an image based on the light receive from the illumination system; and
a projection system adapted to project the image on a screen of the video unit.

17. The video unit of claim 16, comprising an aperture disposed subsequent to the lens.

18. The video unit of claim 16, wherein each of the LEDs is adapted emit red, green or blue light.

19. The video unit of claim 16, wherein the LEDs are disposed within a module that enables independent replacement of each of the LEDs within the illumination system.

20. The video unit of claim 16, wherein each of the plurality of lens elements is disposed about a line joining the plurality of LEDs, the plurality of lens elements and the lens.
